(19) United States
(12) Patent Application Publication
(10) Pub. No.: US 2008/0296673 A1
(43) Pub. Date: Dec. 4, 2008

(54) Double gate manufactured with locos techniques

(75) Inventors: Sung-Shan Tai, San Jose, CA (US); Yongzhong Hu, Cupertino, CA (US)

Correspondence Address: Bo-In Lin, 13445 Mandoli Drive, Los Altos Hills, CA, 94022, US

(73) Assignee: Alpha & Omega Semiconductor, LTD

(21) Appl. No.: 11/807,444

(22) Filed: May 29, 2007

(51) Int. Cl. H01L 29/94; H01L 21/336

(52) U.S. Cl. 257/331; 438/270; 257/E21.409; 257/E29.345

(57) ABSTRACT

This invention discloses a trenched semiconductor power device that includes a trenched gate surrounded by a source region encompassed in a body region above a drain region disposed on a bottom surface of a substrate. The trenched gate further includes at least two mutually insulated trench-filling segments with a bottom insulation layer surrounding a bottom trench-filling segment having a bird-beak shaped layer on a top portion of the bottom insulation attached to sidewalls of the trench extending above a top surface of the bottom trench-filling segment.

### BACKGROUND OF THE INVENTION

1. Field of the Invention

The invention relates generally to the semiconductor power devices. More particularly, this invention relates to an improved and novel manufacturing process and device configuration for providing the semiconductor device with double gates by applying a LOCOS technique.

2. Description of the Prior Art

Conventional technologies for reducing the gate to drain capacitance Cgd in a DMOS device by employing the split trenched-gate, e.g., shielded gate trench (SGT) structure, are still confronted with technical limitations and difficulties. Specifically, trenched DMOS devices are configured with trenched gates wherein large capacitance (Cgd) between gate and drain limits the device switching speed. The capacitance is mainly generated from the electrical field coupling between the bottom of the trenched gate and the drain. In order to reduce the gate to drain capacitance, an improved split trenched-gate configuration, e.g., a Shielded Gate Trench structure (SGT), is introduced with a bottom shielding electrode at the bottom of the trenched gate to shield the trenched gates from the drain. The design concept of a SGT structure is to link the bottom-shielding electrode of the trench to the source such that the trenched gates are shielded from the drain located at the bottom of the substrate as that shown in FIG. 1. A reduction of gate to drain capacitance to about half of the original Cgd value can be achieved by implementing the shielding electrode in the bottom of the trenched gates. The switching speed and switching efficiency of the DMOS devices implemented with the SGT structure are therefore greatly improved. The bottom-shielding electrode when tied to source potential provides a better shielding effect than a configuration where the bottom-shielding segment is left at a floating potential. A reduction of the gate-drain capacitance Cgd is achieved by implementing a bottom poly shielding structure. The problem of break down from trench bottom is eliminated since bottom oxide has a greater thickness than the gate oxide along the trench sidewalls. The net effect is an advantage that for a specific epitaxial thickness, such SGT structure can deliver much higher drain-to-source breakdown voltage (BVdss). Once the BVdss is not a limiting design consideration, the designer has the flexibilities to either increase the doping level or reduce thickness of the epitaxial layer, or to design a device that may accomplish both in order to improve the overall device performance.

However, as shown in FIG. 1, in the manufacturing process, a step of carrying out a wet etch of the first gate oxide often causes a problem of gate oxide weakness. The oxide etch often extends below the top surface of the first polysilicon that have been first deposited into the bottom part of the trench thus causing the formation of an over-etching pocket. Specifically, the sharp and thin inter-poly oxide causes early breakdown between source and gate due to the problems that 1) the dip leads to electric field concentration in the area that causes premature breakdown; and 2) the dip increases a gate-drain overlay thus the Cgd improvement is compromised. Such technical difficulties become a problem when the conventional processes are applied. When applying a conventional manufacturing process, a wet etch process is applied to remove the sidewall oxide that is damaged during first polysilicon etch-back. The isotropic wet-etch process inevitably etches off a portion of sidewall oxide slightly below the top surface of poly creating a pocket on the sidewall. A thermal oxide is grown conformal to the underlying layer forming the upper trench sidewall gate oxide and inter-poly gate oxide followed by second poly deposition. This technical problem and performance limitation often become even more severe when the cell density is increased due to the shrinking dimension of the trench openings when forming the trenched power device in the semiconductor substrate.

Therefore, a need still exists in the art of power semiconductor device design and manufacture to provide new manufacturing method and device configuration in forming the power devices such that the above discussed problems and limitations can be resolved.

### SUMMARY OF THE PRESENT INVENTION

It is therefore an aspect of the present invention to provide a new and improved semiconductor power device implemented with the split trenched-gates where the trenches are opened as a top portion and a bottom portion with the top portion slightly wider than the bottom portion. A thick oxide layer is first form on the sidewalls of the bottom potion thus forming a bird beak shaped layer when extending into the top portion of the sidewalls. The bird beak shaped layer thus preventing an over-etch into the oxide layer to prevent the top segment of polysilicon to extend into an over-etching pocket surrounding the bottom gate segment.

Specifically, it is an aspect of the present invention to provide improved device configuration and manufacturing method to reduce the gate to drain capacitance while accurately control the separation of the top and bottom gate segment by providing a manufacturing process and configuration that the over-etching pocket into the lower oxide layer is prevented by first forming a thick bottom oxide with a bird-beak shaped layer around the top portion of the bottom trench. Special LOCOS processes for forming the bottom thick oxide are applied to provide special advantages of a new structure to reduce Ciss, Coss and Crss to improve the efficiency of Power MOSFET. The new approach will enable the manufacturing process to eliminate the oxide dip back and in the same time to provide the flexibility of improve inter poly oxide to have better reliability.

Briefly in a preferred embodiment this invention discloses a trenched semiconductor power device comprising a trenched gate surrounded by a source region encompassed in a body region above a drain region disposed on a bottom surface of a substrate. The trenched gate further includes at least two mutually insulated trench-filling segments with a bottom insulation layer surrounding a bottom trench-filling segment having a bird-beak shaped layer on a top portion of the bottom insulation attached to sidewalls of the trench extending above a top surface of the bottom trench-filling segment. The trenched semiconductor device further includes an inter-segment insulation layer covering a top surface of the bottom trench-filling segment surrounded by the bird-beak shaped layer. In another exemplary embodiment, the bottom insulation layer has a thickness substantially ranging between 1000 to 3000 Angstroms. In another exemplary embodiment, the trenched gate has a bottom portion surrounded by the bottom insulation layer having a slightly smaller width than a top portion of the trenched gate filled with a top trench-filling segment. In another exemplary embodiment, the bottom insulation layer includes a LOCOS oxide layer. In another exemplary embodiment, the bottom trench-filling segment includes a polysilicon doped with phosphorous or boron. In another exemplary embodiment, the inter-segment insulation layer on the top surface of the bottom trench-filling segment surrounded by LOCOS oxide layer with a top trench-filling segment includes a polysilicon disposed on top of the inter-segment insulation layer. In another exemplary embodiment, the trenched gate further includes a top gate insulation layer surrounding sidewalls of a top portion of the gate trench wherein a ratio between a thickness of the top gate insulation layer to a thickness of the inter-segment insulation layer is substantially between 1:1.2 and 1:5. In another exemplary embodiment, the trenched semiconductor power device constituting a N-channel metal oxide semiconductor field effect transistor (MOSFET) device. In another exemplary embodiment, the trenched semiconductor power device constituting a P-channel MOSFET device. In another exemplary embodiment, the bottom trench-filling segment constituting an electrode electrically connected to the source region of the MOSFET device.

This invention further discloses a method for manufacturing a trenched semiconductor power device that includes step of opening a trench in a semiconductor substrate. The method further includes a step of opening a top portion of the trench first then depositing a SiN on sidewalls of the top portion followed by etching a bottom surface of the top portion of the trench then silicon etching to open a bottom portion of the trench with a slightly smaller width than the top portion of the trench. The method further includes a step of growing a thick oxide layer along sidewalls of the bottom portion of the trench thus forming a bird-beak shaped layer at an interface point between the top portion and bottom portion of the trench. In an exemplary embodiment, the step of growing the thick oxide layer along sidewalls of the bottom portion of the trench further includes a step of growing the thick oxide layer substantially having a thickness ranging from 1000 to 3000 Angstroms. In another exemplary embodiment, the step of growing the thick oxide layer along sidewalls of the bottom portion of the trench further includes a step of applying LOCOS process for growing said thick oxide layer with the bird-beak shaped layer in extending from the bottom portion to the top portion of the trench. The method further includes a step of depositing a polysilicon into the trench followed by doping a phosphorous dopant then etching back the polysilicon to form a bottom trench-filling segment. The method further includes a step of growing a gate oxide and an inter-segment insulation layer with a grow rate ratio between a silicon and a doped polysilicon of 1:1.2 to 1:5. The method further includes a step of forming a top trench-filling segment by applying a second polysilicon deposition with in-situ doped polysilicon followed by a polysilicon etch-back. The method further includes a step of forming body regions by a body implant and driving-in and forming source regions by a source implant and a source diffusion.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIG. 1 is a cross sectional view of a conventional trenched MOSFET device implemented with a trenched gate configured with a conventional split trenched gate trench configuration that shows the uneven etched inter-poly layer.

FIG. 2 is a cross sectional view of a trenched MOSFET device implemented with split trenched gate with a bottom insulation layer having a bird beak shape as manufactured by the process disclosed in this invention.

FIGS. 3A to 3H are a serial cross sectional views for describing the manufacturing processes to provide a trenched MOSFET device as shown in FIG. 2.

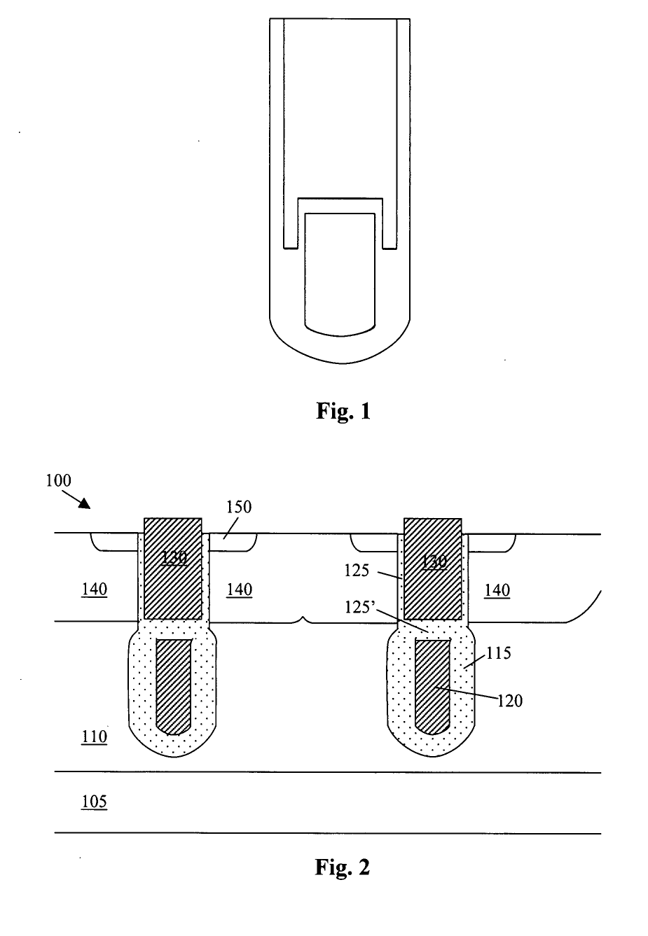

### DETAILED DESCRIPTION OF THE METHOD

Referring to FIG. 2 for a cross sectional view of a trenched MOSFET device 100 of this invention. The trenched MOSFET device 100 is supported on a substrate 105 formed with an epitaxial layer 110. The trenched MOSFET device 100 includes a bottom gate segment 120 filled with polysilicon at the bottom portion below a top trenched gate segment 130. The bottom gate segment 120 filled with the polysilicon is shielded and insulated from a top gate polysilicon segment 130 by an insulation oxide layer 125′ disposed between the top and bottom segments. The bottom trenched-segment is also insulated from the drain disposed below 105 by the insulation layers 115 surrounding the bottom surface of the trenched gate. The top trenched gate segment 130 is also filled with polysilicon in the top portion of the trench surrounded with a gate insulation layer 125 covering the trenched walls.

A body region 140 that is doped with a dopant of second conductivity type, e.g., P-type dopant, extends between the trenched gates 130. The P-body regions 140 encompassing a source region 150 doped with the dopant of first conductivity, e.g., N+ dopant. The source regions 150 are formed near the top surface of the epitaxial layer surrounding the trenched gates 130. On the top surface of the semiconductor substrate are also insulation layers, contact openings and metal layers for providing electrical contacts to the source-body regions and the gates. For the sake of brevity, these structural features are not shown in details and discussed since those of ordinary skill in the art already know these structures.

The bottom oxide layer 115 surrounding the sidewalls of the bottom trenches 120 has a special structural feature that forms a bird beak shape show as the bird beak 115-beak immediately around the inter-polysilicon layer 125′. The inter-poly oxide can be either around or below the bird beak area. The configuration can be flexible and the inter-poly oxide layer is not necessary to be around the bird beak.

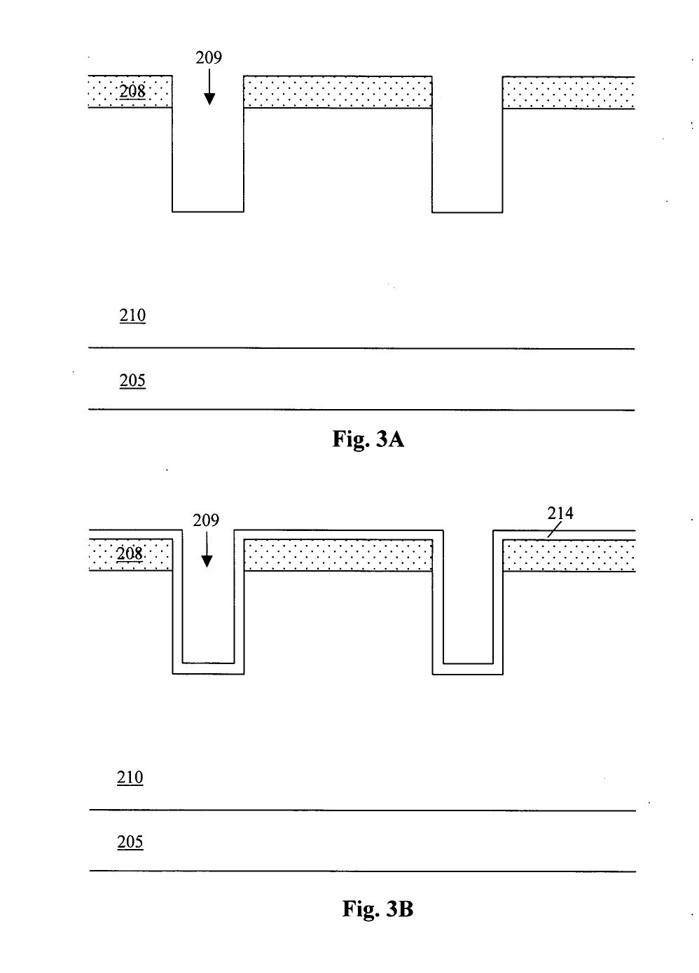

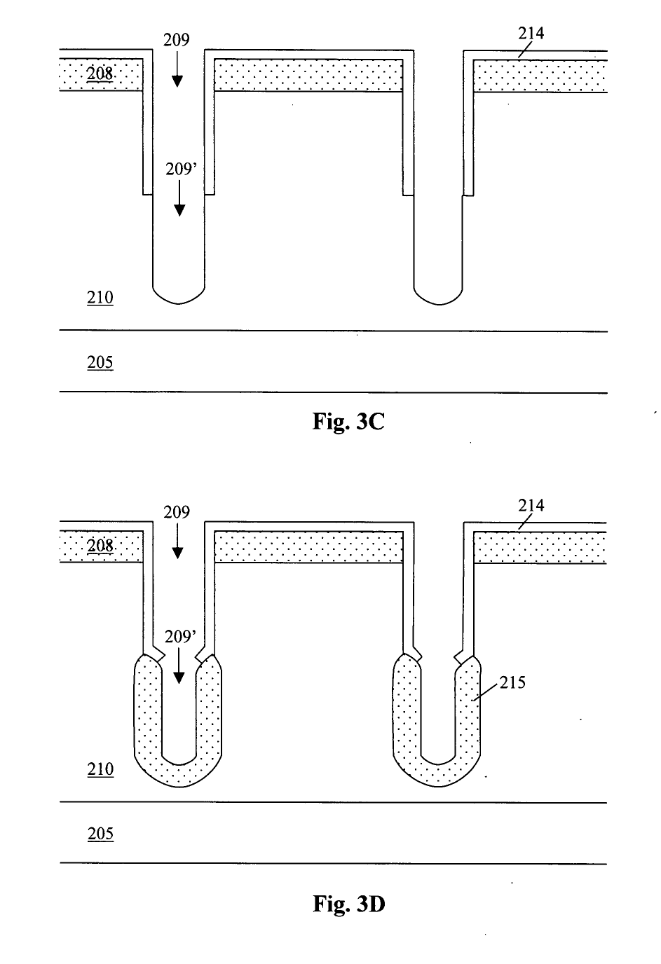

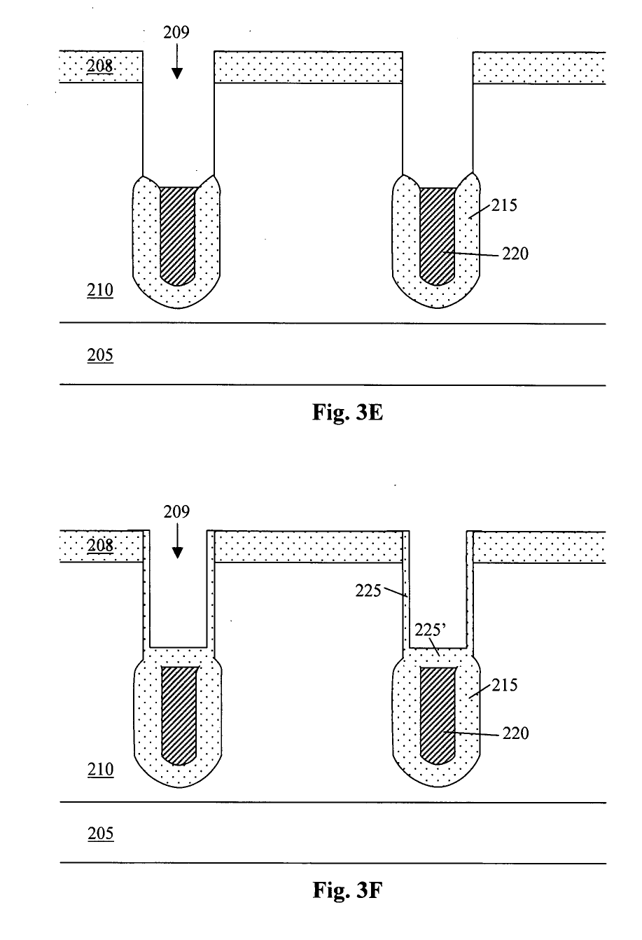

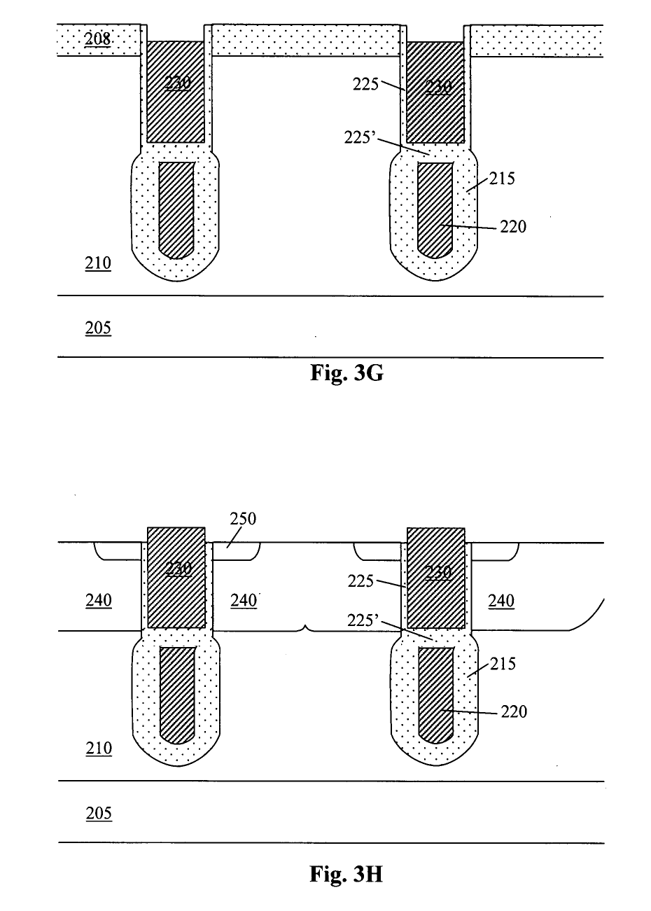

Referring to FIGS. 3A to 3H for a serial of side cross sectional views to illustrate the fabrication steps of a MOSFET device as that shown in FIG. 2. In FIG. 3A, a hard oxide mask 208 is applied to open a plurality of trenches 209 on an epitaxial layer 210 overlaying a substrate 205. In FIG. 3B, an oxide layer (not shown because it is very thin) is grown by a thermal oxide process on the sidewall and bottom surface of the trench 209 having a thickness of about 100 to 300 Angstroms. A silicon nitride layer 214 of about 1000 to 2000 Angstroms of thickness is deposited over the oxide layer just grown. In FIG. 3C, a SiN/SiO2 etch is carried out at the bottom of the trench followed by a silicon etch to open the trench 209 and the bottom trench 209′ to a desired depth. In FIG. 3D, a thick oxide layer 215 is grown on the sidewalls and the bottom surface of the lower trench 209′ with a thickness of about 1000 to 2500 Angstroms and bird beaks are formed at the tops of each lower trench 209′. In FIG. 3E, a wet SiN strip is carried out with hot phosphoric acid to remove the SiN layer 214, and a polysilicon deposition is performed to fill the bottom trench 209's with polysilicon 220. Optionally, a in-situ polysilicon layer 220 is deposited or then a non-doped poly layer is deposited then doped with phosphorous or boron followed by polysilicon etch. A dip off the thin oxide layer is performed; the presence of the bird's beak prevents the undercut of oxide between the polysilicon and silicon. In FIG. 3F, a gate oxide layer 225 is grown with a high differential oxidation rate between the silicon and the doped polysilicon from 1:1.2 to 1:5. Thus the oxide layer 225′ above the polysilicon layer 220 is thicker than the gate oxide layer 225 around the sidewalls. In FIG. 3G, a second polysilicon deposition is carried out with in-situ doped polysilicon to fill the trench with a top polysilicon gate 230 followed by an etch back of the polysilicon from the top surface of the substrate. In FIG. 3H, the hard oxide mask 208 is removed, and a body implant is carried out followed by a body diffusion to form the body regions 240 then a source implant is performed followed by a source diffusion to form the source regions 250. Then standard manufacturing processes are carried out to complete the fabrication of the semiconductor power device.

Although the present invention has been described in terms of the presently preferred embodiment, it is to be understood that such disclosure is not to be interpreted as limiting. Various alterations and modifications will no doubt become apparent to those skilled in the art after reading the above disclosure. Accordingly, it is intended that the appended claims be interpreted as covering all alterations and modifications as fall within the true spirit and scope of the invention.

We claim:

1. A trenched semiconductor power device comprising a trenched gate surrounded by a source region encompassed in a body region above a drain region disposed on a bottom surface of a substrate, wherein:
said trenched gate further includes at least two mutually insulated trench-filling segments with a bottom insulation layer surrounding a bottom trench-filling segment having a bird-beak shaped layer on a top portion of said bottom insulation attached to sidewalls of said trench extending above a top surface of said bottom trench-filling segment.

2. The trenched semiconductor power device of claim 1 further comprising:
an inter-segment insulation layer covering a top surface of said bottom trench-filling segment surrounded by said bird-beak shaped layer.

3. The trenched semiconductor power device of claim 1 wherein:
said bottom insulation layer having thickness substantially ranging between 1000 to 3000 Angstroms.

4. The trenched semiconductor power device of claim 1 wherein:
said trenched gate having a bottom portion surrounded by said bottom insulation layer having a slightly smaller width than a top portion of said trenched gate filled with a top trench-filling segment.

5. The trenched semiconductor power device of claim 1 wherein:
said bottom insulation layer comprising a LOCOS oxide layer.

6. The trenched semiconductor power device of claim 1 wherein:
said bottom trench-filling segment comprising a polysilicon doped with phosphorous.

7. The trenched semiconductor power device of claim 1 further comprising:
an inter-segment insulation layer covering a top surface of said bottom trench-filling segment surrounded by said bird-beak shaped layer with a top trench-filling segment comprising a polysilicon disposed on top of said inter-segment insulation layer.

8. The trenched semiconductor power device of claim 2 wherein:
said trenched gate further comprising a top gate insulation layer surrounding sidewalls of a top portion of said gate trench wherein a ratio between a thickness of said top gate insulation layer to a thickness of said inter-segment insulation layer is substantially between 1.2 to 5.

9. The trenched semiconductor power device of claim 1 wherein:
said trenched semiconductor power device constituting a N-channel metal oxide semiconductor field effect transistor (MOSFET) device.

10. The trenched semiconductor power device of claim 1 wherein:
said trenched semiconductor power device constituting a P-channel MOSFET device.

11. The trenched semiconductor power device of claim 1 wherein:
said bottom trench-filling segment constituting an electrode electrically connected to said source region of said MOSFET device.

12. A trenched MOSFET device comprising a trenched gate surrounded by a source region encompassed in a body region above a drain region disposed on a bottom surface of a substrate, wherein:
said trenched gate further includes at least two mutually insulated trench-filling segments with a bottom oxide layer surrounding a bottom trench-filling segment having a bird-beak shaped layer on a top portion of said bottom insulation attached to sidewalls of said trench extending above a top surface of said bottom trench-filling segment wherein said bottom insulation layer having thickness substantially ranging between 1000 to 3000 Angstroms;
an inter-segment insulation layer covering a top surface of said bottom trench-filling segment surrounded by said bird-beak shaped layer;
said trenched gate having a bottom portion surrounded by said bottom insulation layer having a slightly smaller width than a top portion of said trenched gate filled with a top trench-filling segment;
said bottom trench-filling segment comprising a polysilicon doped with phosphorous or boron; and
said trenched gate further comprising a top gate insulation layer surrounding sidewalls of a top portion of said gate trench wherein a ratio between a thickness of said top gate insulation layer to a thickness of said inter-segment insulation layer is substantially between 1:1.2 and 1:5.

13. The MOSFET device of claim 12 comprising:
a N-channel MOSFET device.

14. The MOSFET device of claim 12 further comprising:
a P-channel MOSFET device.

15. The MOSFET device of claim 12 wherein:
said bottom trench-filling segment constituting an electrode electrically connected to said source region of said MOSFET device.

16. A method for manufacturing a trenched semiconductor power device comprising step of opening a trench in a semiconductor substrate and said method further comprising:
opening a top portion of said trench first then depositing a SiN on sidewalls of said top portion followed by etching a bottom surface of said top portion of said trench then silicon etching to open a bottom portion of said trench with a slightly smaller width than said top portion of said trench.

17. The method of claim 16 further comprising:
growing a thick oxide layer along sidewalls of said bottom portion of said trench thus forming a bird-beak shaped layer at an interface point between said top portion and bottom portion of said trench.

18. The method of claim 17 wherein:
said step of growing said thick oxide layer along sidewalls of said bottom portion of said trench further comprising a step of growing said thick oxide layer substantially having a thickness ranging from 1000 to 3000 Angstroms.

19. The method of claim 17 wherein:
said step of growing said thick oxide layer along sidewalls of said bottom portion of said trench further comprising a step of applying LOCOS process for growing sad thick oxide layer with said bird-beak shaped layer in extending from said bottom portion to said top portion of said trench.

20. The method of claim 17 further comprising:
depositing a polysilicon into said trench followed by doping a N-type dopant followed by etching back said polysilicon to form a bottom trench-filling segment.

21. The method of claim 17 further comprising:
depositing a polysilicon into said trench followed by doping a P-type dopant followed by etching back said polysilicon to form a bottom trench-filling segment.

22. The method of claim 20 further comprising:
growing a gate oxide and an inter-segment insulation layer with a grow rate ration between a silicon and a doped polysilicon up to 1.2 to 5.

23. The method of claim 21 further comprising:
forming a top trench-filling segment by applying a second polysilicon deposition with in-situ doped polysilicon followed by a polysilicon etch-back.

24. The method of claim 22 further comprising:
forming body regions by a body implant and driving-in and forming source regions by a source implant and a source diffusion.
